(19) United States
(12) Patent Application Publication
(10) Pub. No.: US 2024/0380379 A1
(43) Pub. Date: Nov. 14, 2024

(54) ACOUSTIC WAVE DEVICE

(71) Applicant: Murata Manufacturing Co., Ltd., Nagaokakyo-shi (JP)

(72) Inventors: Hiroya SUZUKI, Nagaokakyo-shi (JP); Sunao YAMAZAKI, Nagaokakyo-shi (JP); Toru YAMAJI, Nagaokakyo-shi (JP)

(21) Appl. No.: 18/781,028

(22) Filed: Jul. 23, 2024

Related U.S. Application Data
(63) Continuation of application No. PCT/JP2023/002637, filed on Jan. 27, 2023.
(60) Provisional application No. 63/303,627, filed on Jan. 27, 2022.

(51) Int. Cl. H03H 9/13; H03H 9/05; H03H 9/17

(52) U.S. Cl. CPC H03H 9/13; H03H 9/05; H03H 9/17

(57) ABSTRACT

An acoustic wave device includes an element substrate, a piezoelectric layer, a functional electrode on the piezoelectric layer, and a mounting substrate. The element substrate includes a gap portion at a position overlapping at least a portion of the functional electrode as seen in a lamination direction of the element substrate and the piezoelectric layer, and the mounting substrate includes a ground electrode at a position overlapping the functional electrode in the lamination direction.

### CROSS REFERENCE TO RELATED APPLICATIONS

This application claims the benefit of priority to Provisional Application No. 63/303,627 filed on Jan. 27, 2022 and is a Continuation Application of PCT Application No. PCT/JP2023/002637 filed on Jan. 27, 2023. The entire contents of each application are hereby incorporated herein by reference.

### BACKGROUND OF THE INVENTION

### 1. Field of the Invention

The present disclosure relates to acoustic wave devices each including a piezoelectric layer (piezoelectric body layer).

### 2. Description of the Related Art

For example, Japanese Unexamined Patent Application Publication No. 2012-257019 discloses an acoustic wave device that uses plate waves. The acoustic wave device described in Japanese Unexamined Patent Application Publication No. 2012-257019 includes a support, a piezoelectric substrate, and an IDT electrode. The support has a cavity. The piezoelectric substrate is provided on the support so as to overlap the cavity. The IDT electrode is provided on the piezoelectric substrate so as to overlap the cavity. In the acoustic wave device, a plate wave is excited by the IDT electrode. An end edge portion of the cavity does not include a linear portion extending parallel to the propagation direction of the plate wave excited by the IDT electrode.

### SUMMARY OF THE INVENTION

There has recently been a demand for an acoustic wave device having a membrane structure to be able to reduce ripple.

Example embodiments of the present invention provide acoustic wave devices each capable of reducing ripple.

An acoustic wave device according to an example embodiment of the present disclosure includes an element substrate, a piezoelectric layer, a functional electrode on the piezoelectric layer, and a mounting substrate, in which the element substrate includes a gap portion at a position overlapping at least a portion of the functional electrode as seen in a lamination direction of the element substrate and the piezoelectric layer, and the mounting substrate includes a ground electrode at a position overlapping the functional electrode in the lamination direction.

Example embodiments of the present disclosure provide acoustic wave devices each capable of reducing ripple.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1A is a schematic perspective view illustrating an appearance of an acoustic wave element according to first and second example embodiments of the present disclosure.

FIG. 1B is a plan view illustrating an electrode structure on a piezoelectric layer.

FIG. 2 is a sectional view of a portion taken along line A-A in FIG. 1A.

FIG. 3A is a schematic elevational sectional view for explaining a Lamb wave propagating through a piezoelectric film of an acoustic wave element of the related art.

FIG. 3B is a schematic elevational sectional view for explaining waves of the acoustic wave element according to the present disclosure.

FIG. 4 is a schematic diagram illustrating a bulk wave when a voltage is applied between a first electrode and a second electrode such that the second electrode has a higher potential than the first electrode.

FIG. 5 is a graph illustrating resonance characteristics of the acoustic wave element according to an example embodiment of the present invention.

FIG. 6 is a graph illustrating the relationship between d/2p and a fractional band width of a resonator in the acoustic wave element.

FIG. 7 is a plan view of another acoustic wave element according to an example embodiment of the present invention.

FIG. 8 is a reference diagram illustrating an example of the resonance characteristics of the acoustic wave element.

FIG. 9 is a graph illustrating the relationship between a fractional band width and a phase rotation amount of a spurious impedance normalized by 180 degrees as a magnitude of spurious when a large number of acoustic wave resonators are configured.

FIG. 10 is a graph illustrating the relationship among d/2p, a metallization ratio MR, and a fractional band width.

FIG. 11 is a graph illustrating a map of the fractional band width with respect to Euler angles (0°, θ, ψ) of LiNbO₃ when d/p is infinitely close to 0.

FIG. 12 is a partially cutaway perspective view for explaining an acoustic wave element according to an example embodiment of the present invention.

FIG. 13 is a schematic sectional view illustrating an example of an acoustic wave device according to an example embodiment of the present invention.

FIG. 14 is a schematic top view illustrating a functional electrode, a wiring electrode, and a mounting substrate having a ground electrode of the acoustic wave device in FIG. 13.

FIG. 15 is a graph for explaining that the acoustic wave device in FIG. 13 has smaller ripple than an acoustic wave device including no ground electrode.

FIG. 16 is an enlarged view of a portion indicated by a dashed circle in FIG. 15.

FIG. 17 is a schematic plan view illustrating modification of the acoustic wave device in FIG. 12.

### DETAILED DESCRIPTION OF THE EXAMPLE EMBODIMENTS

Hereinafter, example embodiments of the present disclosure will be described with reference to the accompanying drawings. The following description is merely exemplary in nature and is not intended to limit the present disclosure, the application of the present disclosure, or the use of the present disclosure. The drawings are schematic, and dimensional ratios and the like do not necessarily correspond to the actual ones.

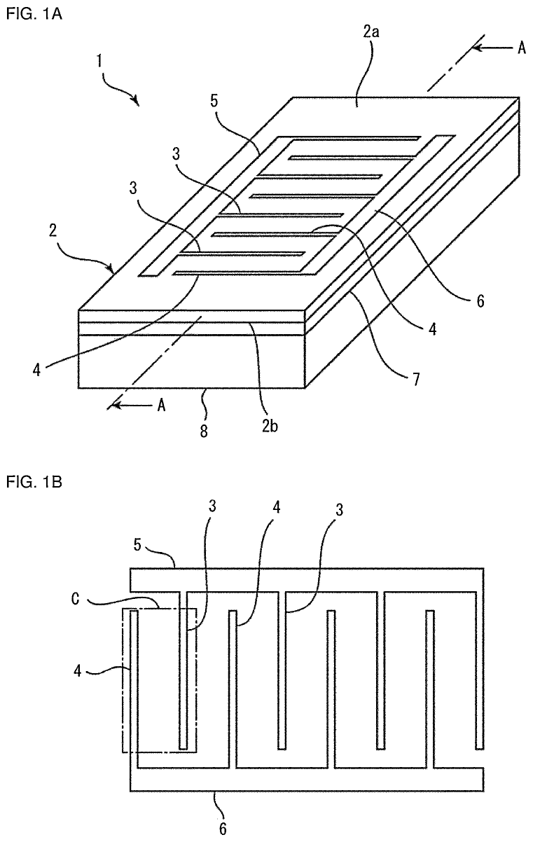

With reference to FIGS. 1A to 12, acoustic wave devices according to first to fourth aspects on which example embodiments of the present disclosure are based will be described.

An acoustic wave element according to the first, second, and third aspects of example embodiments of the present disclosure include a piezoelectric layer made of lithium niobate or lithium tantalate, for example, and a first electrode and a second electrode facing each other in a direction intersecting the thickness direction of the piezoelectric layer.

An acoustic wave element according to the first aspect of example embodiments of the present disclosure uses a bulk wave in a first-order thickness-shear mode.

In the acoustic wave element according to the second aspect of example embodiments of the present disclosure, the first electrode and the second electrode are adjacent to each other, and d/p is less than or equal to about 0.5, for example, where d is the thickness of the piezoelectric layer, and p is the center-to-center distance between the first electrode and the second electrode. With this configuration, in the first and second aspects of example embodiments of the present disclosure, a Q value can be increased even when the size of the acoustic wave device is reduced.

The acoustic wave element according to the third aspect of example embodiments of the present disclosure uses a Lamb wave as a plate wave. The Lamb wave can provide resonance characteristics.

An acoustic wave element according to the fourth aspect of example embodiments of the present disclosure includes a piezoelectric layer made of lithium niobate or lithium tantalate, and an upper electrode and a lower electrode facing each other in the thickness direction of the piezoelectric layer with the piezoelectric layer interposed therebetween, and uses a bulk wave.

The present disclosure will be clarified by describing specific example embodiments of the acoustic wave elements according to the first to fourth aspects of example embodiments of the present disclosure below with reference to the drawings.

It should be noted that each example embodiment described in this specification is illustrative, and partial substitution or combination of configurations described in different example embodiments is possible.

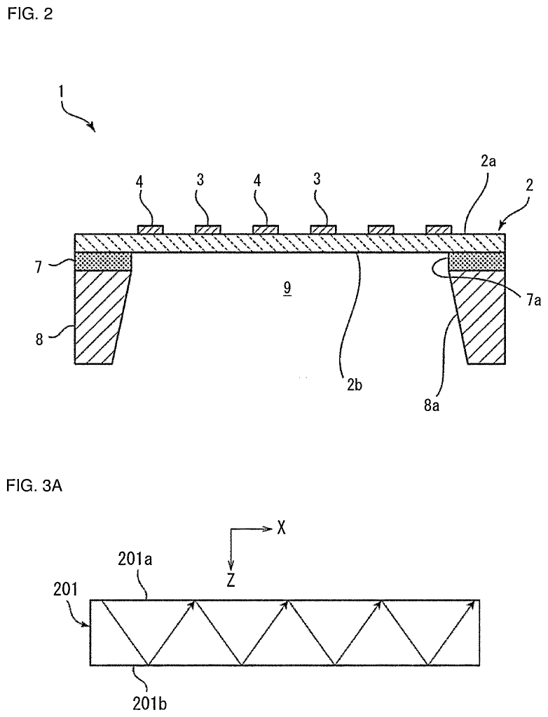

FIG. 1A is a schematic perspective view illustrating an appearance of an acoustic wave element according to an example embodiment of the first and second aspects of example embodiments of the present disclosure. FIG. 1B is a plan view illustrating an electrode structure on a piezoelectric layer. FIG. 2 is a sectional view of a portion taken along line A-A in FIG. 1A.

An acoustic wave element 1 includes a piezoelectric layer 2 made of LiNbO₃. The piezoelectric layer 2 may be made of LiTaO₃. The cut-angle of LiNbO₃ or LiTaO₃ is a Z-cut in this example embodiment, but may be a rotated Y-cut or X-cut. The propagation directions of Y propagation and X propagation about ±30° are preferable, for example. The thickness of the piezoelectric layer 2 is not particularly limited, but is preferably more than or equal to about 50 nm and less than or equal to about 1000 nm in order to effectively excite the first-order thickness-shear mode, for example.

The piezoelectric layer 2 includes a first main surface 2a and a second main surface 2b facing each other. An electrode 3 and an electrode 4 are provided on the first main surface 2a. Here, the electrode 3 is an example of a “first electrode” and the electrode 4 is an example of a “second electrode”. In FIGS. 1A and 1B, a plurality of electrodes 3 are a plurality of “first electrode fingers” connected to a first busbar 5. A plurality of electrodes 4 are a plurality of “second electrode fingers” connected to a second busbar 6. The plurality of electrodes 3 and the plurality of electrodes 4 are interdigitated with each other.

The electrode 3 and the electrode 4 each have a rectangular or substantially rectangular shape and have a length direction. In a direction orthogonal to the length direction, the electrode 3 and the electrode 4 adjacent thereto face each other. An interdigital transducer (IDT) electrode is thus provided, including the plurality of electrodes 3 and 4, the first busbar 5, and the second busbar 6. The length direction of the electrodes 3 and 4 and the direction orthogonal to the length direction of the electrodes 3 and 4 each are a direction intersecting a thickness direction of the piezoelectric layer 2. Therefore, it can also be said that the electrode 3 and the electrode 4 adjacent thereto face each other in a direction intersecting the thickness direction of the piezoelectric layer 2.

Further, the length direction of the electrodes 3 and 4 may be replaced with the direction orthogonal to the length direction of the electrodes 3 and 4 illustrated in FIGS. 1A and 1B. That is, the electrodes 3 and 4 may extend in the direction in which the first busbar 5 and the second busbar 6 extend in FIGS. 1A and 1B. In this case, the first busbar 5 and the second busbar 6 extend in the direction in which the electrodes 3 and 4 extend in FIGS. 1A and 1B.

A plurality of pairs of structures in which the electrode 3 connected to one potential and the electrode 4 connected to the other potential are adjacent to each other are provided in the direction orthogonal to the length direction of the electrodes 3 and 4 described above. Here, the electrode 3 and the electrode 4 being adjacent to each other refers not to a case where the electrode 3 and the electrode 4 are arranged so as to be in direct contact with each other but to a case where the electrode 3 and the electrode 4 are arranged with an interval therebetween.

In addition, when the electrode 3 and the electrode 4 are adjacent to each other, an electrode connected to a hot electrode or a ground electrode, including the other electrodes 3 and 4, is not arranged between the electrode 3 and the electrode 4. The number of pairs need not be integer pairs, but may be 1.5 pairs, 2.5 pairs, or the like. The center-to-center distance between the electrodes 3 and 4, that is, the pitch is preferably in the range of more than or equal to about 1 μm and less than or equal to about 10 μm, for example. In addition, the center-to-center distance between the electrodes 3 and 4 is a distance connecting the center of the width dimension of the electrode 3 in the direction orthogonal to the length direction of the electrode 3 and the center of the width dimension of the electrode 4 in the direction orthogonal to the length direction of the electrode 4. Further, in a case where at least one of the electrodes 3 and 4 includes a plurality of electrodes (when the electrodes 3 and 4 define a pair of electrodes and there are 1.5 or more pairs of electrodes), the center-to-center distance between the electrodes 3 and 4 refers to the average value of the center-to-center distances between the respective adjacent electrodes 3 and 4 of the 1.5 or more pairs of electrodes 3 and 4. In addition, the width of the electrodes 3 and 4, that is, the dimension of the electrodes 3 and 4 in their facing direction, is preferably in the range of more than or equal to about 150 nm and less than or equal to about 1000 nm, for example. The center-to-center distance between the electrodes 3 and 4 is a distance connecting the center of the dimension (width dimension) of the electrode 3 in the direction orthogonal to the length direction of the electrode 3 and the center of the dimension (width dimension) of the electrode 4 in the direction orthogonal to the length direction of the electrode 4.

In this example embodiment, since the Z-cut piezoelectric layer is used, the direction orthogonal to the length direction of the electrodes 3 and 4 is a direction orthogonal to the polarization direction of the piezoelectric layer 2. This does not apply when a piezoelectric body of another cut-angle is used as the piezoelectric layer 2. Here, “orthogonal” is not limited to strictly orthogonal but may be substantially orthogonal (an angle between the direction orthogonal to the length direction of the electrodes 3 and 4 and the polarization direction is, for example, about 90°±10°).

A support 8 is laminated on the second main surface 2b side of the piezoelectric layer 2 with an insulating layer (also referred to as a junction layer) 7 interposed therebetween. The insulating layer 7 and the support 8 have a frame shape and include cavities 7a and 8a as illustrated in FIG. 2. A gap portion 9 is thus provided. The gap portion 9 is provided so as not to interfere with the vibration of an excitation region C of the piezoelectric layer 2. Therefore, the support 8 is laminated on the second main surface 2b with the insulating layer 7 interposed therebetween at a position not overlapping a portion where at least a pair of electrodes 3 and 4 are provided. Note that the insulating layer 7 need not be provided. Therefore, the support 8 can be directly or indirectly laminated on the second main surface 2b of the piezoelectric layer 2.

The insulating layer 7 is made of silicon oxide. However, the insulating layer 7 can be made of an appropriate insulating material such as silicon oxynitride or alumina in addition to silicon oxide. The support 8 is made of Si. The plane orientation of the surface of Si on the piezoelectric layer 2 side may be (100), (110), or (111). Preferably, high-resistance Si having a resistivity of more than or equal to about 4 kQ is preferable, for example. However, the support 8 can also be made using an appropriate insulating material or semiconductor material. Examples of the material of the support 8 include piezoelectric bodies such as aluminum oxide, lithium tantalate, lithium niobate, or quartz crystal; various ceramics such as alumina, magnesia, sapphire, silicon nitride, aluminum nitride, silicon carbide, zirconia, cordierite, mullite, steatite, or forsterite; dielectrics such as diamond or glass, and semiconductors such as gallium nitride; or the like.

The plurality of electrodes 3 and 4 and the first and second busbars 5 and 6 are made of an appropriate metal or alloy such as Al or an AlCu alloy. In this example embodiment, the electrodes 3 and 4 and the first and second busbars 5 and 6 have a structure in which an Al film is laminated on a Ti film. An adhesion layer other than the Ti film may be used.

At the time of driving, an AC voltage is applied between the plurality of electrodes 3 and the plurality of electrodes 4. More specifically, an AC voltage is applied between the first busbar 5 and the second busbar 6. This makes it possible to obtain resonance characteristics using a bulk wave in the first-order thickness-shear mode excited in the piezoelectric layer 2.

In the acoustic wave element 1, d/p is less than or equal to about 0.5, for example, where d is the thickness of the piezoelectric layer 2, and p is the center-to-center distance between any adjacent electrodes 3 and 4 of the plurality of pairs of electrodes 3 and 4. Therefore, the bulk wave in the first-order thickness-shear mode is effectively excited, and good resonance characteristics can be obtained. More preferably, d/p is less than or equal to about 0.24, for example, in which case even better resonance characteristics can be obtained.

In a case where at least one of the electrodes 3 and 4 includes a plurality of electrodes as in this example embodiment, that is, in a case where the electrodes 3 and 4 define a pair of electrodes and there are 1.5 or more pairs of the electrodes 3 and 4, the center-to-center distance p between the adjacent electrodes 3 and 4 is an average distance of the center-to-center distances between the respective adjacent electrodes 3 and 4.

Since the acoustic wave element 1 according to this example embodiment has the configuration described above, a Q value is less likely to be reduced even when the number of pairs of the electrodes 3 and 4 is reduced in an attempt to achieve a reduction in size. This is because the resonator does not require reflectors on both sides and has a small propagation loss. In addition, the reason why the above reflector is not required is that the bulk wave in the first-order thickness-shear mode is used.

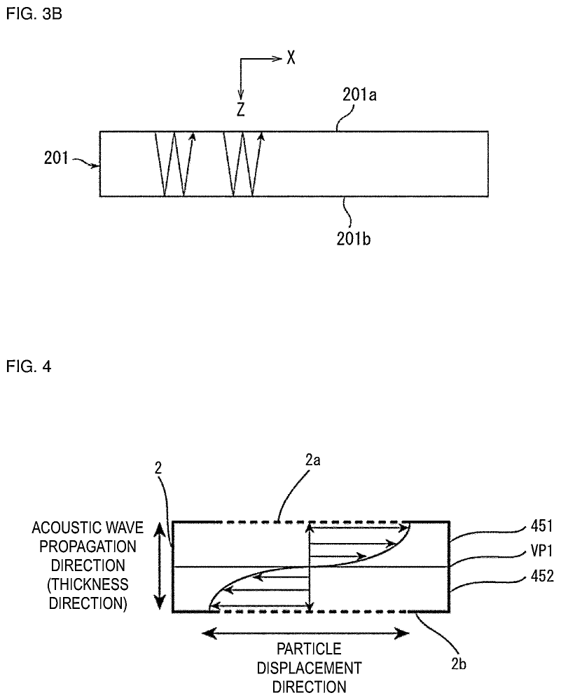

With reference to FIGS. 3A and 3B, description will be given of the difference between a Lamb wave used in an acoustic wave element of the related art and the bulk wave in the first-order thickness-shear mode described above.

FIG. 3A is a schematic elevational sectional view for explaining a Lamb wave propagating through a piezoelectric film in the acoustic wave element of the related art. The acoustic wave element of the related art is described in Japanese Unexamined Patent Application Publication No. 2012-257019, for example. As illustrated in FIG. 3A, in the acoustic wave element of the related art, a wave propagates through a piezoelectric layer 201 as indicated by arrows. Here, a first main surface 201a and a second main surface 201b of the piezoelectric layer 201 face each other, and a thickness direction connecting the first main surface 201a and the second main surface 201b is a Z direction. An X direction is a direction in which electrode fingers of an IDT electrode are arranged. As illustrated in FIG. 3A, the Lamb wave propagates in the X direction. Although the piezoelectric layer 201 vibrates as a whole because of the plate wave, since the wave propagates in the X direction, reflectors are arranged on both sides to obtain resonance characteristics. Therefore, a propagation loss of waves occurs, and the Q value decreases when the size is reduced, that is, when the number of pairs of electrode fingers is reduced.

On the other hand, as illustrated in FIG. 3B, in the acoustic wave element 1 of this example embodiment, since the vibration displacement is in the thickness-shear direction, the wave substantially propagates in the direction connecting the first main surface 2a and the second main surface 2b of the piezoelectric layer 2, that is, the Z direction, and resonates. Specifically, the X direction component of the wave is significantly smaller than the Z direction component. Since resonance characteristics are obtained by the propagation of the wave in the Z direction, a reflector is not required. Therefore, propagation loss when the wave propagates to the reflector does not occur. Therefore, even when the number of pairs of electrodes including the electrodes 3 and 4 is reduced in an attempt to reduce the size, the Q value is less likely to be reduced.

As illustrated in FIG. 4, the amplitude direction of the bulk wave in the first-order thickness-shear mode in a first region 451 included in the excitation region C of the piezoelectric layer 2 is opposite the amplitude direction thereof in a second region 452 included in the excitation region C. FIG. 4 schematically illustrates a bulk wave when a voltage is applied between the electrode 3 and the electrode 4 so that the electrode 4 has a higher potential than the electrode 3. The first region 451 is a region between the first main surface 2a and a virtual plane VP1 that is orthogonal to the thickness direction of the piezoelectric layer 2 and divides the piezoelectric layer 2 into two parts in the excitation region C. The second region 452 is a region between the virtual plane VP1 and the second main surface 2b in the excitation region C.

As described above, in the acoustic wave element 1, at least a pair of electrodes including the electrode 3 and the electrode 4 are arranged. Since waves are not propagated in the X direction, the plurality of pairs of electrodes including the electrodes 3 and 4 are not always necessary. That is, only one pair of electrodes may be provided.

For example, the electrode 3 is an electrode connected to the hot potential and the electrode 4 is an electrode connected to the ground potential. However, the electrode 3 may be connected to the ground potential and the electrode 4 may be connected to the hot potential. In this example embodiment, as described above, at least a pair of electrodes are the electrode connected to the hot potential or the electrode connected to the ground potential, and a floating electrode is not provided.

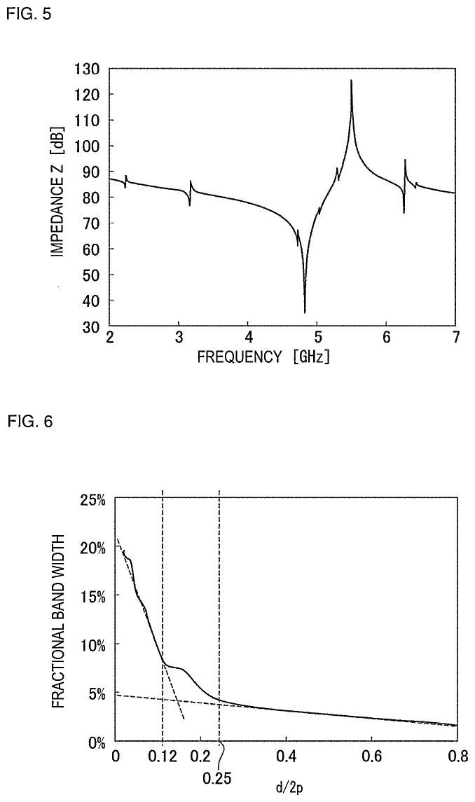

FIG. 5 is a graph illustrating the resonance characteristics of the acoustic wave element according to an example embodiment of the present disclosure. The design example parameters of the acoustic wave element 1 having the resonance characteristics are as follows.
Piezoelectric layer 2: LiNbO₃ with Euler angles (0°, 0°, 90°)
Thickness: 400 nm
Length of region where electrodes 3 and 4 overlap as seen in a direction orthogonal to length direction of electrodes 3 and 4, that is, excitation region C: 40 μm
Number of pairs of electrodes including electrodes 3 and 4: 21 pairs
Center-to-center distance between electrodes: 3 μm
Width of electrodes 3 and 4: 500 nm
d/p: 0.133 Insulating layer 7: silicon oxide film with thickness of
1 μm
Support 8: Si

The length of the excitation region C is a dimension of the excitation region C in the length direction of the electrodes 3 and 4.

In this example embodiment, the center-to-center distances of the electrode pairs including the electrodes 3 and 4 are all equal in the plurality of pairs. That is, the electrodes 3 and the electrodes 4 are arranged with equal pitches.

As is clear from FIG. 5, good resonance characteristics with the fractional band width of about 12.5% are obtained even though no reflector is provided.

As described above, in this example embodiment, d/p is less than or equal to about 0.5, more preferably less than or equal to about 0.24, for example, where d is the thickness of the piezoelectric layer 2 and p is the center-to-center distance between the electrode 3 and the electrode 4. This will be described with reference to FIG. 6.

A plurality of acoustic wave elements are obtained in the same manner as the acoustic wave element having the resonance characteristics illustrated in FIG. 5, except that d/2p is changed. FIG. 6 is a graph illustrating the relationship between d/2p and a fractional band width of a resonator in the acoustic wave element.

As illustrated in FIG. 6, when d/2p exceeds about 0.25, that is, d/p>about 0.5, for example, the fractional band width is less than 5% even when d/p is adjusted. On the other hand, when d/2p≤about 0.25, that is, d/p≤about 0.5, for example, the fractional band width can be more than or equal to about 5% by changing d/p within the range, that is, the resonator having a high coupling coefficient can be provided. When d/2p is less than or equal to about 0.12, that is, d/p is less than or equal to about 0.24, the fractional band width can be increased to more than or equal to about 7%, for example. In addition, when d/p is adjusted within this range, a resonator having a wider fractional band width can be obtained, and a resonator having a higher coupling coefficient can be realized. Therefore, as in the case of the acoustic wave element according to the second aspect of example embodiments of the present disclosure, it is understood that by setting d/p to less than or equal to about 0.5, for example, a resonator having a high coupling coefficient using the bulk wave in the first-order thickness-shear mode described above can be provided.

Note that, as described above, the at least one pair of electrodes may be a pair of electrodes, and in the case of one pair of electrodes, p is the center-to-center distance between the adjacent electrodes 3 and 4. Further, in the case of 1.5 or more pairs of electrodes, p may be the average distance of the center-to-center distances between the adjacent electrodes 3 and 4.

When the piezoelectric layer 2 has variations in thickness d, a value obtained by averaging the thicknesses may be used.

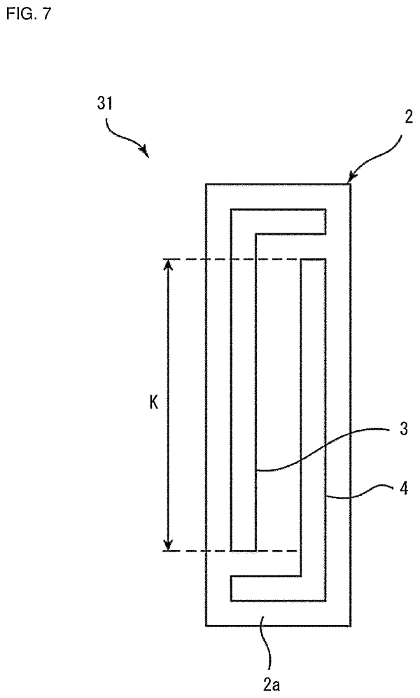

FIG. 7 is a plan view of another acoustic wave element according to an example embodiment of the present disclosure. In an acoustic wave element 31, a pair of electrodes including the electrode 3 and the electrode 4 are provided on the first main surface 2a of the piezoelectric layer 2. K in FIG. 7 is an intersecting width. As described above, in the acoustic wave element 31 of an example embodiment of the present disclosure, the number of pairs of electrodes may be one. Also in this case, when d/p is less than or equal to about 0.5, for example, the bulk wave in the first-order thickness-shear mode can be effectively excited.

In the acoustic wave element 1, it is preferable that the metallization ratio MR of any adjacent electrodes 3 and 4 of the plurality of electrodes 3 and 4 with respect to the excitation region C, which is a region where the adjacent electrodes 3 and 4 overlap as seen in their facing direction, satisfies MR≤about 1.75 (d/p)+0.075, for example. In other words, a region where the plurality of first electrode fingers and the plurality of second electrode fingers overlap as seen in a direction in which the adjacent first electrode fingers and second electrode fingers face each other is an excitation region (intersection region), and it is preferable that MR≤about 1.75 (d/p)+0.075 is satisfied, for example, where MR is the metallization ratio of the plurality of first electrode fingers and the plurality of second electrode fingers to the excitation region. In that case, it is possible to effectively reduce spurious.

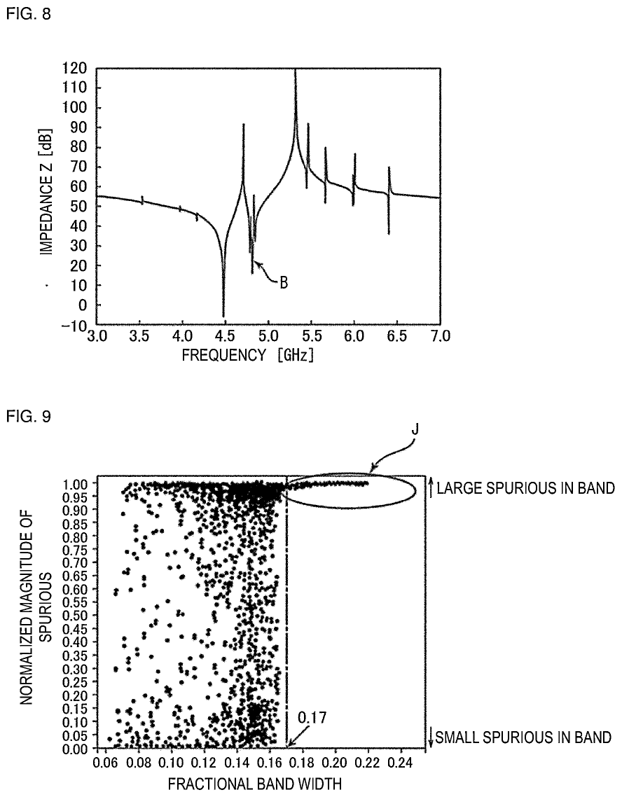

This will be described with reference to FIGS. 8 and 9. FIG. 8 is a reference diagram illustrating an example of the resonance characteristics of the acoustic wave element 1 described above. A spurious indicated by an arrow B appears between a resonant frequency and an anti-resonant frequency. Note that d/p=about 0.08 and the Euler angles of LiNbO₃ are approximately (0°, 0°, 90°), for example. The metallization ratio MR is about 0.35, for example.

The metallization ratio MR will be described with reference to FIG. 1B. In the electrode structure of FIG. 1B, when a pair of electrodes 3 and 4 are focused on, it is assumed that only the pair of electrodes 3 and 4 are provided. In this case, a portion surrounded by a dashed-dotted line is the excitation region C. When the electrode 3 and the electrode 4 are viewed in the direction orthogonal to the length direction of the electrodes 3 and 4, that is, viewed in their facing direction, the excitation region is a region of the electrode 3 that overlaps the electrode 4, a region of the electrode 4 that overlaps the electrode 3, and a region between the electrode 3 and the electrode 4 where the electrode 3 and the electrode 4 overlap each other. An area of the electrodes 3 and 4 in the excitation region C with respect to the area of the excitation region is the metallization ratio MR. That is, the metallization ratio MR is the ratio of the area of the metallization portion to the area of the excitation region.

When a plurality of pairs of electrodes are provided, the ratio of the metallization portion included in the entire excitation region to the total area of the excitation region may be MR.

FIG. 9 is a graph illustrating a relationship between a fractional band width and a phase rotation amount of spurious impedance normalized by 180 degrees as the magnitude of the spurious when a large number of acoustic wave resonators are configured according to this example embodiment. The fractional band width is adjusted by changing the film thickness of the piezoelectric layer and the dimensions of the electrodes. FIG. 9 illustrates the results when a Z-cut LiNbO₃ piezoelectric layer is used, but the same tendency is obtained also when piezoelectric layers with other cut-angles are used.

In a region surrounded by an ellipse J in FIG. 9, the spurious is as large as about 1.0, for example. As is clear from FIG. 9, when the fractional band width exceeds about 0.17, that is, exceeds about 17%, for example, a large spurious with a spurious level of more than or equal to 1 appears in a pass band even when the parameters defining the fractional band width are changed. That is, as in the resonance characteristics illustrated in FIG. 8, a large spurious indicated by the arrow B appears within the band. Therefore, the fractional band width is preferably less than or equal to about 17%, for example. In this case, the spurious can be reduced by adjusting the film thickness of the piezoelectric layer 2, the dimensions of the electrodes 3 and 4, or the like.

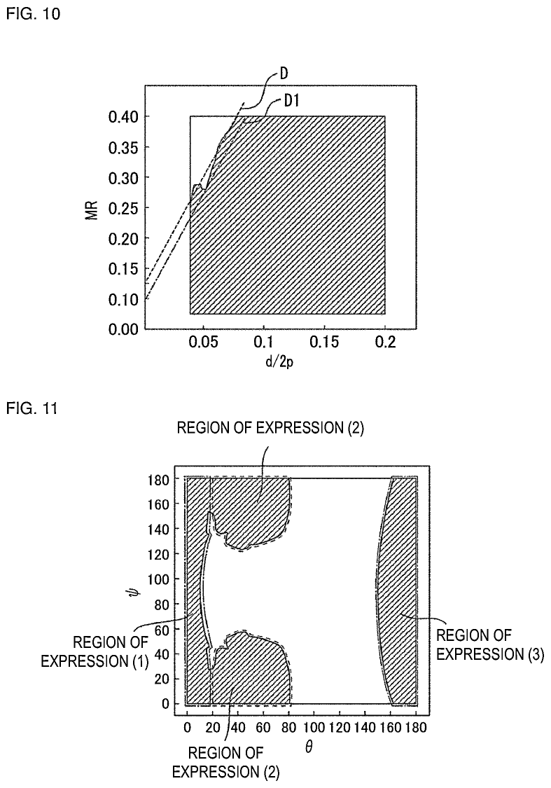

FIG. 10 is a graph illustrating a relationship among d/2p, the metallization ratio MR, and the fractional band width. In the acoustic wave element described above, various acoustic wave elements having different values of d/2p and different values of MR are provided, and the fractional band width is measured. A hatched portion to the right of a dashed line D illustrated in FIG. 10 is a region where the fractional band width is less than or equal to about 178, for example. The boundary between the hatched region and the non-hatched region is represented by MR=about 3.5 (d/2p)+0.075, for example. That is, MR=about 1.75 (d/p)+0.075, for example. Therefore, MR≤about 1.75 (d/p)+0.075 is preferably satisfied, for example. In this case, the fractional band width is more likely to be less than or equal to about 17%, for example. It is more preferable to be the region in FIG. 10 to the right of a dashed-dotted line D1 indicating MR=about 3.5 (d/2p)+0.05, for example. That is, when MR≤about 1.75 (d/p)+0.05, the fractional band width can be reliably set to less than or equal to about 17%, for example.

FIG. 11 is a graph illustrating a map of the fractional band width with respect to the Euler angles (0°, θ, ψ) of LiNbO₃ when d/p is infinitely close to 0. A hatched portion in FIG. 11 is a region where the fractional band width of at least more than or equal to about 5% is obtained, for example, and the range of the region is approximated by Expressions (1), (2), and (3) below.

(0°±10°, 0° to 20°, any ψ) Expression (1)

(0°±10°, 20° to 80°, 0° to 60° (1−(θ−50)²/900)^{1/2}) or (0°±10°, 20° to 80°, [180°−60° (1−(θ−50)²/900)^{1/2}] to 180°) Expression (2)

(0°±10°, [180°−30° (1−(ψ−90)²/8100)^{1/2}] to 180°, any ψ) Expression (3)

Therefore, in the case of the Euler angle range of Expression (1), Expression (2), or Expression (3), the fractional band width can be sufficiently widened, which is preferable.

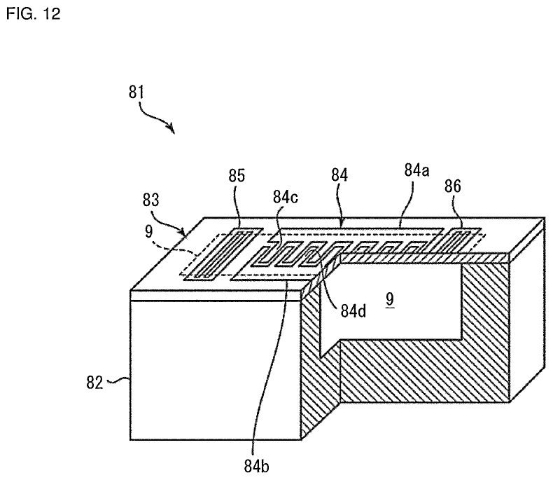

FIG. 12 is a partially cutaway perspective view for explaining an acoustic wave element according to an example embodiment of the present disclosure. An acoustic wave element 81 includes a support substrate 82. The support substrate 82 includes a recessed portion in its upper surface. A piezoelectric layer 83 is laminated on the support substrate 82. This defines a gap portion 9. An IDT electrode 84 is provided on the piezoelectric layer 83 above the gap portion 9. Reflectors 85 and 86 are provided on both sides of the IDT electrode 84 in the acoustic wave propagation direction. In FIG. 12, the outer periphery of the gap portion 9 is indicated by a dashed line. Here, the IDT electrode 84 has a first busbar 84a, a second busbar 84b, electrodes 84c as a plurality of first electrode fingers, and electrodes 84d as a plurality of second electrode fingers. The plurality of electrodes 84c are connected to the first busbar 84a. The plurality of electrodes 84d are connected to the second busbar 84b. The plurality of electrodes 84c and the plurality of electrodes 84d are interdigitated with each other.

In the acoustic wave element 81, a Lamb wave as a plate wave is excited by applying an AC electric field to the IDT electrode 84 above the gap portion 9. Since the reflectors 85 and 86 are provided on both sides, resonance characteristics due to the Lamb wave can be obtained.

As described above, the acoustic wave element of the present disclosure may use a plate wave.

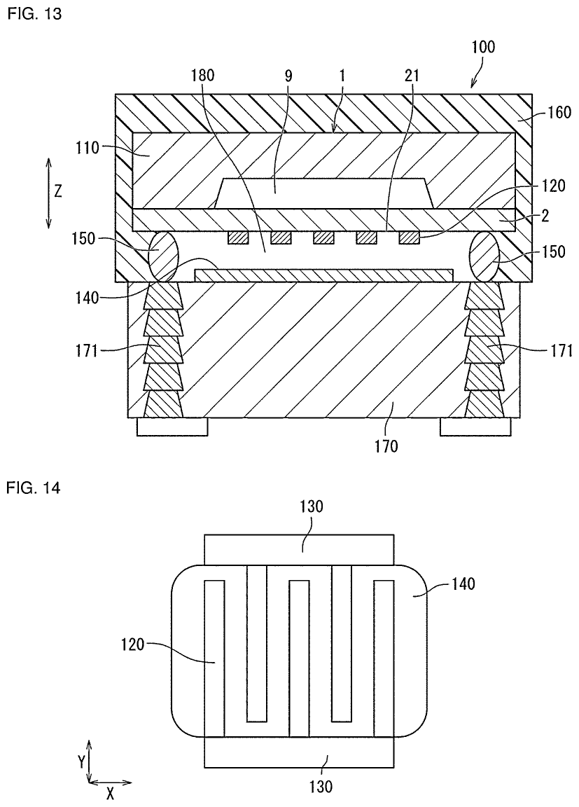

With reference to FIGS. 13 to 17, an acoustic wave device 100 according to an example embodiment of the present disclosure will be described. In this example embodiment, the description of contents that overlap with the acoustic wave devices of the first to fourth aspects of example embodiments of the present disclosure will be omitted as appropriate. In the following description, the description of the acoustic wave devices of the first to fourth aspects of example embodiments of the present disclosure can be applied.

As illustrated in FIG. 13, the acoustic wave device 100 includes an acoustic wave element 1, metal bumps 150, a sealing resin 160, and a mounting substrate 170.

The acoustic wave element 1 includes an element substrate 110, a piezoelectric layer 2, and a functional electrode 120, which are laminated in this order. The piezoelectric layer 2 is provided on the element substrate 110, and the functional electrode 120 is provided on the piezoelectric layer 2. In this example embodiment, the acoustic wave element 1 includes a wiring electrode 130 that is provided on the piezoelectric layer 2 and electrically connected to the functional electrode 120.

The element substrate 110 includes a gap portion 9 at a position that overlaps a portion of the functional electrode 120 in plan view in the lamination direction (for example, Z direction) of the element substrate 110, the piezoelectric layer 2, and the functional electrode 120. The functional electrode 120 is located between two wiring electrodes 130 (see FIG. 14) provided on the piezoelectric layer 2. The two wiring electrodes 130 are spaced apart from each other in a direction intersecting the lamination direction Z. In FIG. 14, components other than the functional electrode 120, the wiring electrodes 130, and a ground electrode 140 are omitted.

The functional electrode 120 is an IDT electrode having a plurality of electrode fingers, for example, and is located between the two wiring electrodes 130 spaced apart from each other in the direction (for example, Y direction) intersecting the lamination direction Z, as illustrated in FIG. 14. The plurality of electrode fingers of the functional electrode 120 each extend in the Y direction and are located at intervals in the X direction. Each electrode finger of the functional electrode 120 is connected to one of the two wiring electrodes 130.

The mounting substrate 170 has the ground electrode 140 that faces the functional electrode 120 in the lamination direction Z and overlaps the functional electrode 120 in the lamination direction Z. In this example embodiment, the ground electrode 140 is configured to overlap the entire intersection region of the functional electrode 120 as seen in the lamination direction Z, as illustrated in FIG. 14. One main surface of the piezoelectric layer 2 on which the functional electrode 120 is located faces the mounting surface of the mounting substrate 170 on which the ground electrode 140 is located. The metal bumps 150 are located between one main surface of the piezoelectric layer 2 and the mounting surface of the mounting substrate 170 to electrically connect the wiring electrodes 130 to a conductive layer 171 included in the mounting substrate 170, thus providing a space between the piezoelectric layer 2 and the mounting substrate 170. That is, an air layer 180 or a dielectric layer (when the functional electrode 120 is covered with a dielectric film, which is not shown) is interposed between the ground electrode 140 and the functional electrode 120. The ground electrode 140 and the functional electrode 120 directly face each other, without anything interposed therebetween except the air layer 180 or the dielectric layer.

The sealing resin 160 surrounds the acoustic wave element 1 and the metal bumps 150, together with the mounting substrate 170, and seals the acoustic wave element 1 and the metal bumps 150.

The acoustic wave element including a membrane structure includes a gap portion below the piezoelectric layer, and functional electrodes are arranged on the piezoelectric layer so as to at least partially overlap the gap portion. In this acoustic wave element, spurious originating from the membrane (in other words, originating from the hollow space below the piezoelectric layer) may be generated in a pass band used as a filter and in the vicinity of the pass band, causing the potential of the functional electrode to be unstable.

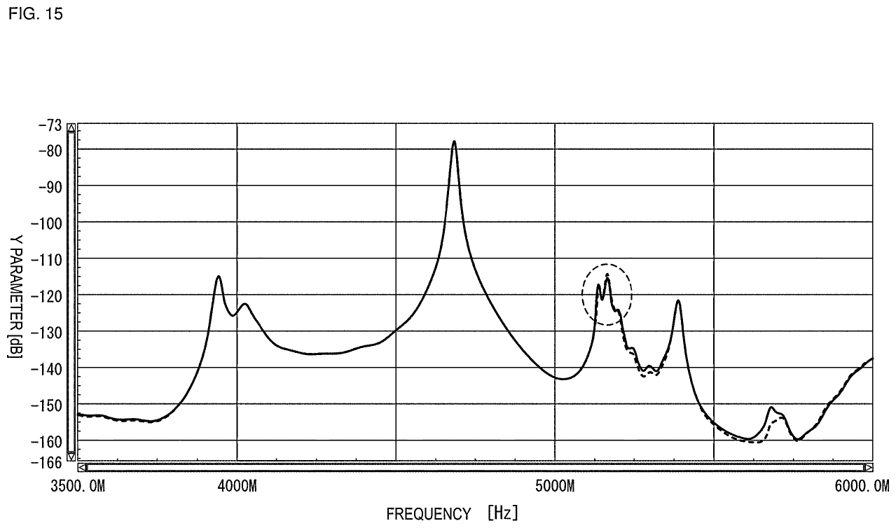

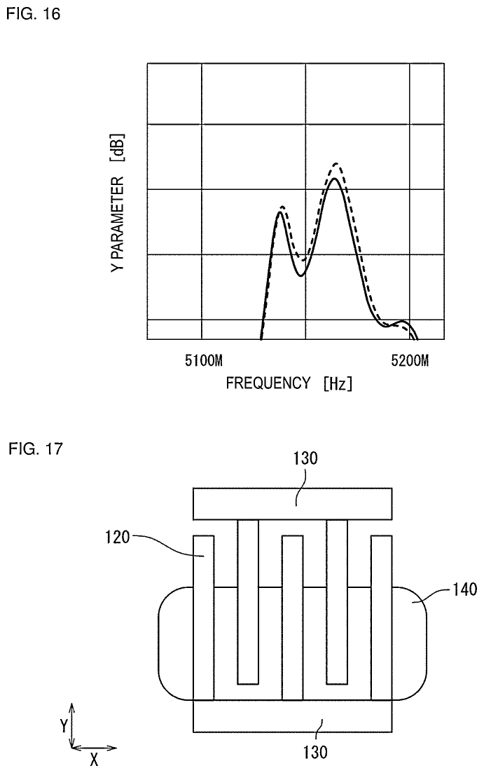

The acoustic wave device 100 includes the acoustic wave element 1 and the mounting substrate 170. The acoustic wave element 1 includes the element substrate 110, the piezoelectric layer 2, and the functional electrode 120, which are laminated in this order. The element substrate 110 includes the gap portion 9 provided at a position overlapping a portion of the functional electrode 120, as seen in the lamination direction Z of the element substrate 110, the piezoelectric layer 2, and the functional electrode 120. The mounting substrate 170 includes the ground electrode 140 that overlaps the functional electrode 120 in the lamination direction Z. The potential of the ground electrode 140 stabilizes the potential of the functional electrode 120, and reduces the displacement of the potential of the functional electrode 120. That is, as illustrated in FIGS. 15 and 16, a ripple generated in the acoustic wave device 100 is smaller than that in an acoustic wave device that does not include the ground electrode 140. As a result, an acoustic wave device capable of reducing the ripple can be realized.

In FIGS. 15 and 16, the logarithm of the real part of Y parameter of the acoustic wave device 100 having the ground electrode 140 is indicated by a solid line, while the logarithm of the real part of Y parameter of the acoustic wave device without the ground electrode 140 is indicated by a dashed line. The Y parameter is a parameter to check when resonance is observed, and the real part is the frequency characteristic of admittance. The acoustic wave device without the ground electrode 140 has the same configuration as the acoustic wave device 100 except the presence or absence of the ground electrode 140. FIG. 16 is an enlarged view of a portion indicated by a dashed circle in FIG. 15. As illustrated in FIGS. 15 and 16, the acoustic wave device 100 has a smaller Y parameter and smaller ripple in the frequency band corresponding to loss when a filter is formed, compared to the acoustic wave device without the ground electrode 140.

The acoustic wave device 100 can also be configured as follows.

The ground electrode 140 is not limited to being configured so as to overlap the entire intersection region of the functional electrode 120 as seen in the lamination direction Z, but may be configured so as to overlap a portion of the intersection region of the functional electrode 120, as illustrated in FIG. 17.

A layer of another configuration, without being limited to the dielectric layer or the air layer 180, may be formed between the functional electrode 120 and the ground electrode 140. The acoustic wave element 1 can be manufactured using any method, such as a method of forming the gap portion 9 using a sacrificial layer, or a method of etching the element substrate 110 from the back side.

The element substrate 110 may include a support and an insulating layer provided on the support, or may include the support only.

At least a portion of the configuration of the acoustic wave device 100 of the present disclosure may be added to the acoustic wave devices of the first to fourth aspects of example embodiments of the present disclosure, or at least a portion of the configuration of the acoustic wave devices of the first to fourth aspects of example embodiments of the present disclosure may be added to the acoustic wave device 100 of the present disclosure.

Various example embodiments of the present disclosure have been described in detail above with reference to the drawings.

Any of the various example embodiments or modifications may be appropriately combined to achieve the effects thereof. In addition, combinations of example embodiments, combination of examples, or combinations of example embodiments and examples is possible, or combinations of features of different example embodiments or examples are also possible.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
an element substrate;
a piezoelectric layer;
a functional electrode on the piezoelectric layer; and
a mounting substrate; wherein
the element substrate includes a gap portion at a position overlapping at least a portion of the functional electrode as seen in a lamination direction of the element substrate and the piezoelectric layer; and
the mounting substrate includes a ground electrode at a position overlapping the functional electrode in the lamination direction.

2. The acoustic wave device according to claim 1, wherein a dielectric layer or an air layer is interposed between the functional electrode and the ground electrode.

3. The acoustic wave device according to claim 1, wherein the element substrate includes a support and a junction layer between the support and the piezoelectric layer.

4. The acoustic wave device according to claim 1, wherein the functional electrode is an interdigital transducer electrode.

5. The acoustic wave device according to claim 4, wherein
the piezoelectric layer includes lithium niobate or lithium tantalate;
the interdigital transducer electrode includes a first electrode finger and a second electrode finger facing each other in a direction intersecting the lamination direction;
the first electrode finger and the second electrode finger are adjacent to each other; and
d/p is less than or equal to about 0.5, where d is a film thickness of the piezoelectric layer and p is a center-to-center distance between the first electrode finger and the second electrode finger.

6. The acoustic wave device according to claim 5, wherein d/p is less than or equal to about 0.24.

7. The acoustic wave device according to claim 5, wherein MR≤about 1.75 (d/p)+0.075 is satisfied, where MR is a metallization ratio that is a ratio of an area of the first electrode finger and the second electrode finger in an excitation region relative to the excitation region, the excitation region being a region where the first electrode finger and the second electrode finger overlap in the direction intersecting the lamination direction.

8. The acoustic wave device according to claim 5, wherein
Euler angles (φ, θ, ψ) of the lithium niobate or lithium tantalate are within a range of Expression (1), Expression (2), or Expression (3):
(0°±10°, 0° to 20°, any ψ) Expression (1)
(0°±10°, 20° to 80°, 0° to 60° (1−(θ−50)²/900)^{1/2}) or (0°±10°, 20° to 80°, [180°−60° (1−(θ−50)²/900)^{1/2}] to 180°) Expression (2)
(0°±10°, [180°−30° (1−(ψ−90)²/8100)^{1/2}] to 180°, any ψ) Expression (3)

9. The acoustic wave device according to claim 4, wherein
the piezoelectric layer includes lithium niobate or lithium tantalate; and
the acoustic wave device is structured to use a bulk wave in a thickness-shear mode.

10. The acoustic wave device according to claim 1, wherein the acoustic wave device is structured to use a plate wave.

11. The acoustic wave device according to claim 1, wherein the acoustic wave device is structured to use a Lamb wave.

12. The acoustic wave device according to claim 4, wherein the interdigital transducer includes only one pair of electrodes.

13. The acoustic wave device according to claim 4, wherein the interdigital transducer includes only a plurality of pairs of electrodes.

14. The acoustic wave device according to claim 1, further comprising reflectors on both sides of the functional electrode.

15. The acoustic wave device according to claim 1, wherein no reflector is provided on the piezoelectric layer.

16. The acoustic wave device according to claim 1, further comprising a wiring electrode on the piezoelectric layer and electrically connected to the functional electrode.

17. The acoustic wave device according to claim 1, wherein the functional electrode is located between two wiring electrodes.

18. The acoustic wave device according to claim 17, wherein the functional electrode is an interdigital transducer electrode including electrode fingers connected to the two wiring electrodes.

19. The acoustic wave device according to claim 1, wherein the mounting substrate overlaps an entire intersection region of the functional electrode.

20. The acoustic wave device according to claim 17, further comprising metal bumps between the piezoelectric layer and the mounting substrate to electrically connect the two wiring electrodes to a conductive layer in the mounting substrate and to provide a space between the piezoelectric layer and the mounting substrate.
